(19) United States
(12) Patent Application Publication
(10) Pub. No.: US 2025/0240890 A1
(43) Pub. Date: Jul. 24, 2025

(54) METHOD OF EMBEDDING AN EMBEDDABLE OBJECT INTO A STACKED SUBSTRATE AND STACKED SUBSTRATE ARRANGEMENT

(71) Applicant: Infineon Technologies AG, Neubiberg (DE)

(72) Inventors: Thomas GEBHARD, Villach (AT); Toni SALMINEN, München (DE); Mahadi-Ul HASSAN, Regensburg (DE)

(73) Assignee: Infineon Technologies AG, Neubiberg (DE)

(21) Appl. No.: 19/032,804

(22) Filed: Jan. 21, 2025

(30) Foreign Application Priority Data
Jan. 24, 2024 (DE) 10 2024 101 946.8

(51) Int. Cl. H05K 1/14; B32B 37/02; B32B 37/12; B32B 37/24; B32B 38/00; H05K 1/03; H05K 3/36

(52) U.S. Cl. CPC H05K 1/144; B32B 37/02; B32B 37/1284; B32B 37/24; B32B 38/0004; H05K 1/0366; H05K 3/36; B32B 2457/08

(57) ABSTRACT

A method of embedding an embeddable object into a stacked substrate is provided. The method may include forming a stacked substrate including a first layer and a second layer disposed over the first layer, and embedding material disposed between the first layer and the second layer. The embeddable object is disposed into a recess of the stacked substrate. A portion of the embedding material is transferred from a high viscosity or solid state into a low viscosity state so that at least a portion of the embedding material flows into the recess to laterally fix the embeddable object within the recess to the stacked substrate.

### CROSS-REFERENCE TO RELATED APPLICATION

This Utility Patent Application claims priority to German Patent Application No. 10 2024 101 946.8 filed Jan. 24, 2024, which is incorporated herein by reference.

### TECHNICAL FIELD

Various embodiments relate generally to a method of embedding an embeddable object into a stacked substrate and to a stacked substrate arrangement.

### BACKGROUND

Contact surfaces (e. g., contact pads and the like) of dies or embeddable objects are presently provided with a copper layer through electro-less Cu plating to maximize a galvanic-connection area for forming interconnects to surrounding elements or devices.

An adhesion promotor surface treatment may be needed before embedding the chip embedding (CE-)inlay further into a semiconductor arrangement like a PCB.

Even though it may be possible to apply an adhesion promoter to an inlay, such a treated surface may have a limited shelf life.

For example, the surface may be very susceptible for scratches and dirt (as visual criteria), but furthermore, further oxidation may take place on the surface.

Known printed circuit board (PCB) surface finishes are not an option for improving a surface adhesion.

On the one hand, the PCB may contain foreign materials (e. g., organic solderable preservatives (OSP), and/or silver (Ag)), which may compromise reliability, and/or a surface finish like for example an electroless nickel immersion gold (ENIG) or an electroless gold plating may be used as a protective coating on a copper surface, which may have a rather low adhesion, in particular to a PCB resin.

At present, a PCB manufacturer may require a special fixture or a basket to be able to run the CE-inlays through an adhesion promotor surface treatment process.

However, after treatment, some handling and, for example, pick-and-place processing may to be done. There is a high probability that the treated surface may be damaged during such processing performed after the surface treatment.

At least in high-volume manufacturing, a care that may be required to prevent damage during handling may not be provided during high-volume manufacturing.

### SUMMARY

A method of embedding an embeddable object into a stacked substrate is provided. The method may include forming a stacked substrate including a first layer and a second layer disposed over the first layer, and embedding material disposed between the first layer and the second layer, disposing the embeddable object into a recess of the stacked substrate, and transferring a portion of the embedding material from a solid state or a high viscosity into a low viscosity state, so that at least a portion of the embedding material flows into the recess to laterally fix the embeddable object within the recess to the stacked substrate.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a flow diagram of a method of embedding an embeddable object into a stacked substrate in accordance with various embodiments;

FIG. 2, panels a), b), c), d) and e), visualize a method of embedding an embeddable object into a stacked substrate in accordance with various embodiments through several schematic drawings showing processes used in the method;
each of FIG. 3A, panels a), b), c); FIG. 3B, panels a), b); and FIG. 3C, panels a), b), c), d), e), visualize a method of embedding an embeddable object into a stacked substrate in accordance with various embodiments through several schematic drawings showing processes used in the method.

FIG. 4, panels a), b), c), d), visualize a method of embedding an embeddable object into a stacked substrate in accordance with various embodiments through several schematic drawings showing processes used in the method;

FIG. 5, panels a), b), c), d), visualize a method of embedding an embeddable object into a stacked substrate in accordance with various embodiments through several schematic drawings showing processes used in the method;

FIG. 6, panels a), b), c), d), e), visualize a method of embedding an embeddable object into a stacked substrate in accordance with various embodiments through several schematic drawings showing processes used in the method;

FIG. 7, panels a), b), c), d), visualize a method of embedding an embeddable object into a stacked substrate in accordance with various embodiments through several schematic drawings showing processes used in the method; and

FIG. 8, panels a), b), c), d), visualize a method of embedding an embeddable object into a stacked substrate in accordance with various embodiments through several schematic drawings showing processes used in the method;

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

In various embodiments, a stacked substrate with an embedded embeddable object is provided using a specific laminate material stack-up and standard PCB manufacturing processes to fix and include the embeddable object, for example the embeddable object, as part of the PCB core structure. When the embeddable object(s) is/are fixed to the core, its/their outer surfaces, e. g., Cu surfaces, may be exposed.

This may make it possible for a PCB manufacturer to continue to use their standard panel-level manufacturing process.

In various embodiments, a PCB/substrate material lay-up construction may be used to fix an embeddable object or feature during a PCB manufacturing process to reduce a necessity of handling small objects, improve the objects' tolerances in the process and enhance further processability in PCB/substrate manufacturing, in particular with respect to panel level processing.

An embedding material may, according to various embodiments, be provided from a center of the stacked substrate (also referred to as “centerline” concept).

This may allow to reduce a panel-level warpage compared to unbalanced structures when embedding or encapsulating objects into a PCB/substrate (e. g., if a flowable material is for example single-sided, or if the structure is double-sided but has imbalanced flowable-material thicknesses).

In various embodiments, an embeddable object may be embedded into a PCB/substrate core layer as follows: a selected material stack structure of surrounding materials (sheets/laminates/ply/etc.) may be provided.

A sticky-tape/removable adhesive may be applied to a bottom of the laminate stack covering a cavity in the laminate stack, for a die-attach process that may be used to keep the die stable in X-Y during an initial lamination process.

After placing the die in the cavity on the sticky-tape, another removable adhesive may be applied on top of the stack.

Subsequently, a vacuum, pressure and/or temperature may be applied to a resin that may be located in the middle of the stack, such that the resin becomes flowable (along a center-line of the stack), which will cause the resin to flow into the cavity, surround the embeddable object in the cavity, and thereby fix the embeddable object to the surrounding material stack when the resin is either partly or fully cured.

During the initial lamination, the sticky-tape on top may cover (e. g., be in contact with) the top-side metallization and protect it from contaminating with flowing resin.

After the sticky-tape removal, the laminate stack may be processed in standard PCB/substrate panel-size processes.

As a consequence, subsequent processes like e-less contacting/plating, or for example a surface adhesion promotion process (e. g., a brown-oxide process) may be conducted on the embedded object on a panel level as part of a normal PCB/substrate production process.

The method of embedding an embeddable object in a laminate stack may work on any ML-core lamination structure where an external object may need to be fixed into a cavity in a PCB.

A lateral resin flow from within a stacked structure may be initiated during a lamination process. Thereby, an embeddable object may be laterally fixed to the stacked structure.

FIG. 2 visualizes a method of embedding an embeddable object 102 into a stacked substrate 104 in accordance with various embodiments. Thereby, a stacked substrate arrangement 100 may be formed.

The stacked substrate 104 may be provided. The stacked substrate 104 includes a first layer 106, a second layer 108 disposed over the first layer 108, and embedding material 110 arranged between the first layer 106 and the second layer 108.

The stacked substrate 104 may for example include or consist of a laminate.

The first layer 106 and/or the second layer 108 may include or consist of an insulating material, for example glass reinforced epoxy laminate such as FR-4. The (e. g., insulating) material of the first layer 106 and/or of the second layer 108 may have a melting temperature that is higher than a melting temperature of the embedding material 110.

In various embodiments, the first layer 106 and/or the second layer 108 may (e. g., additionally) include a metal layer 116, e. g. a copper layer (such an exemplary embodiment is indicated in some of the figures; the term “CCL” may refer to a copper-clad layer) or an aluminum layer, on one or both of their respective main surfaces.

The first layer 106 and/or the second layer 108 may for example be configured as printed circuit boards (PCBs).

Optionally, for example in a case where it may be essential that a warpage of the stacked substrate 104 may be prevented, the first layer 106 and the second layer 110 have the same thickness.

The stacked substrate 104 may further include an embedding material 110 between the first layer 106 and the second layer 108.

The embedding material 110 may be disposed between the first layer 106 and the second layer 108 as a continuous layer, as shown in the exemplary embodiment of FIG. 2, or as a structured layer.

The embedding material 110 includes or consists of a material that is transferrable from a solid state or a high viscosity to a low viscosity, e. g., a flowing state, at least once. In the final stacked substrate arrangement 100, the embedding material 110 is in the solid state (or in a high viscosity state; in the following, unless it is explicitly stated or clear from the context that this does not apply, the solid state is to be understood to include also a state of high viscosity). The embedding material 110 may for example include or consist of a thermoplastic polymer, for example polypropylene, a resin (e. g., PrePreg with a high-resin content or a resin film), a mold film, or a bonding film (e. g., ABF—Ajinomoto Bonding Film).

When in the low viscosity state, e. g., the flowing state, the embedding material 110 may have a viscosity in a range from about 1 mPa·s to about 10⁷ mPa·s.

A thickness of the embedding material 110 between the first layer 106 and the second layer 108 in the final stacked substrate arrangement 100 may be in a range from about 1 μm to less than 10 mm.

The stacked substrate 104 may further include a recess 112, also referred to as cavity, formed in the first layer 106 and/or the second layer 108.

The recess 112 may be formed as a through-hole that extends through the first layer 106, the second layer 108, and through the embedding material 110. Alternatively, the recess 112 may extend only partially through the stacked substrate 104. For example, a portion of the first layer 104 may remain, forming a bottom of the recess 112 and an outer surface of the stacked substrate 104.

The recess 112 may essentially be formed as known in the art, for example by (e. g., laser) cutting or other techniques.

The stacked substrate arrangement 100 may further include an embeddable object 102 arranged in the recess 112. The embeddable object 102 may, as indicated in the figures, include or consist of a semiconductor component, e. g. a bare die, having metal layers 120 (e. g., contact pads) on its top surface (also referred to as its top metal layer) and/or on its bottom surface (also referred to as its bottom metal layer), respectively. In various other embodiments, the embeddable object 102 may for example include or consist of any other circuit component that may suitably be arranged inside a stacked substrate 104, for example a passive component like a capacitor or a resistor, a contact element like an electrically conductive block like a Cu coin, or for example a magnet or a sensor element.

The stacked substrate arrangement 100 may further include the embedding material 110 extending into the recess 112. The embedding material 110 in the recess 112 laterally fixes the embeddable object 102 within the recess 112 to the stacked substrate 104.

The embedding material 110 in the recess 112 originates from an embedding material reservoir between the first layer 106 and the second layer 108 (of which the embedding material 110 that is still present in the final stacked substrate arrangement 100 between the first layer 106 and the second layer 108 is a remnant), such that the embedding material 110 in the recess 112 is homogeneously connected to the embedding material 110 between the first layer 106 and the second layer 108. In other words, no material inhomogeneity may be found between the embedding material 110 in the cavity 112 and the embedding material 110 between the first layer 106 and the second layer 108, since the embedding material 110 had been deposited, in its low viscosity, e. g., its flowing state, in a lateral flow from the area between the first layer 106 and the second layer 108 into the cavity 112, and was then transferred, essentially as a single entity, to its solid state.

In various embodiments, a bottom surface of the embeddable object 102 may be flush with a surface of the first layer 106 that faces towards a bottom of the stacked substrate 104, and/or a top surface of the embeddable object 102 may be flush with a surface of the second layer 108 that faces towards a top of the stacked substrate 104.

The top surface and/or the bottom surface of the embeddable object 102 may be free from the embedding material 110. Alternatively, the bottom surface and/or the top surface may be covered by the embedding material.

The embedding material 110 may, in various embodiments, contact the embeddable object 102 only laterally, or additionally on at least one of a top surface and a bottom surface of the embeddable object 102.

FIG. 2 illustrates in panels a) through e) how the above described stacked substrate arrangement 100 may be formed in accordance with various embodiments.

As indicated in panel a), a bottom of the recess 112 may be closed by an auxiliary carrier 114, for example an adhesive sheet or sticky tape.

As indicated in panel b), a top of the recess 112 may be closed by another auxiliary carrier 118, for example an adhesive sheet or sticky tape.

The arrows above panel c) are meant to indicate how the partial transfer of the embedding material 110 from the embedding material reservoir between the first layer 106 and the second layer 108 is achieved: Pressure from an outside, heat, and/or a vacuum applied to the cavity may for example be used.

Applying pressure from the outside may for example include pressing the first layer 106 against the second layer 108, such that the embedding material 110 flows into the recess 112, which is to be understood to mean that the first layer 106 and the second layer 108 are pressed towards each other, irrespective of whether the first layer 106 is moved towards the second layer 108 or vice versa, or whether both layers are moved towards each other.

Once the recess 112 is filled (as in FIG. 2, panel c)), or at least the embeddable object 102 sufficiently covered laterally, the embedding material 110 may be transferred to its solid state, for example by curing (e. g., using ultraviolet radiation, allowing the embedding material 110 to passively cool, or cooling it actively, or any other technique known in the art.

Subsequently, the auxiliary carriers 114, 118 may be removed (see panel d)), and an optional post-processing may be performed, for example a depositing of a metal (e. g., copper) layer 122 over a bottom and/or top of the stacked substrate arrangement 100 (see panel e). The deposited metal 122 may be in contact with a bottom metal layer 120 and/or with a top metal layer 120.

The deposited metal 122 may in various embodiments form a galvanic connection, e. g., a direct galvanic connection, between the top metal layer 120 of the embeddable object 102 and a metal layer 116 on a top side of the stacked substrate, and/or form a galvanic connection, e. g., a direct galvanic connection, between the bottom metal layer 120 of the embeddable object 102 and a metal layer 116 on a bottom side of the stacked substrate.

Each of FIGS. 3A to 8 shows details or alternatives to what was described in context with the embodiment of FIG. 2 of the method of embedding the embeddable object 102 into a stacked substrate 104.

Each of FIGS. 3A and 3B shows in particular the stacked substrate 104.

In FIG. 3A, panels a), b) and c), the lamination process is shown, wherein the first layer 106 and the second layer 108 are each copper clad layers (CCL) having a copper layer 116 on each of their main surfaces.

In FIG. 3B, panels a) and b), a stacked substrate 104 is formed/provided that is basically similar to the exemplary embodiment of FIG. 3A, but the copper layer 116 may be present on only the outer surfaces of the first layer 106 and the second layer 108, respectively, i. e., on the bottom surface of the first layer 106, and on the top surface of the second layer 108.

FIG. 3C, panels a), b), c) and d), visualize an embodiment with a structured layer of embedding material 110.

In panel a), the first layer 106 (in this exemplary embodiment with metal layers 116 on both surfaces; as an alternative, only one or none of the surfaces may be metallized) is provided, with its portion of the recess 112 already formed.

In panel b), the embedding material 110 is arranged as a continuous layer on top of the first layer 106.

Subsequently, as shown in panel c), the embedding material 110 is structured. by forming a plurality of openings in the layer, for example by etching or other suitable techniques as known in the art.

As an alternative, also the embedding material 110 may be provided as a pre-structured layer.

In panel d), the second layer 108 (in this exemplary embodiment with metal layers 116 on both surfaces; as an alternative, only one or none of the surfaces may be metallized) is arranged on top of the embedding material 110, with its portion of the recess 112 already formed. The first layer 106 and the second layer 108 sandwich the embedding material 110 between them.

Panel e) shows the resulting configuration after arranging the embeddable object 102 in the recess 112 and transferring a portion of the embedding material 110, when it was in a low viscosity, e. g., a flowing state, from its original location between the first layer 106 and the second layer 108 to the recess 112.

In the recess 112, the embedding material 110 laterally contacts and—after solidifying—fixes the embeddable object 102 in the recess 112 and thereby to the stacked substrate 104.

The recess 112, in particular a portion underneath the embeddable object 110, is not filled by the embedding material 110.

Such a configuration may for example be achieved by using an embedding material 110 that has, in its low viscosity, e. g., flowing state, a relatively high viscosity, for example a viscosity between about 1 Pa·s and about 10⁴ Pa·s, for example with a viscosity comparable to butter or dough.

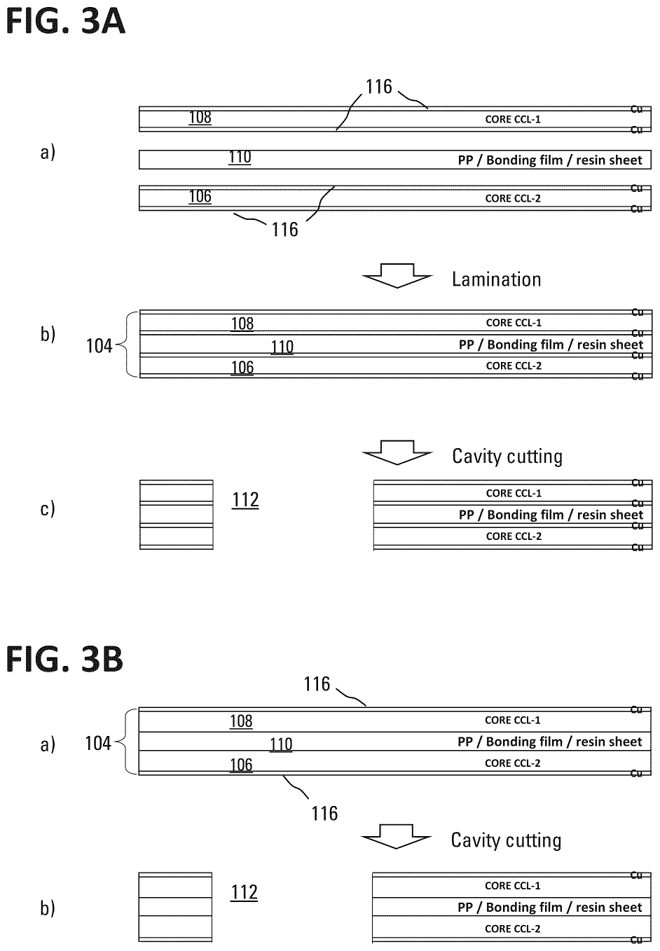

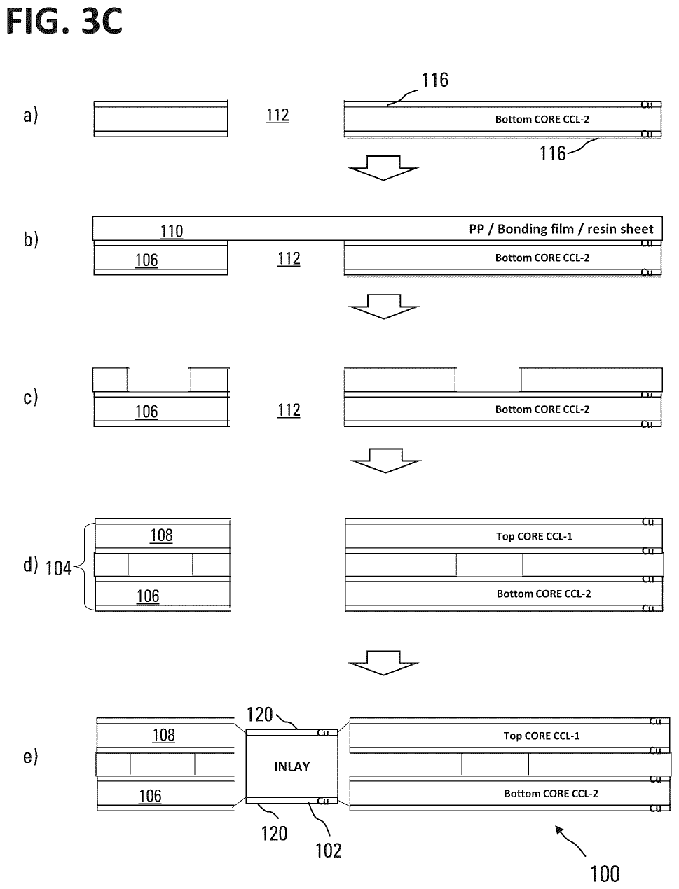

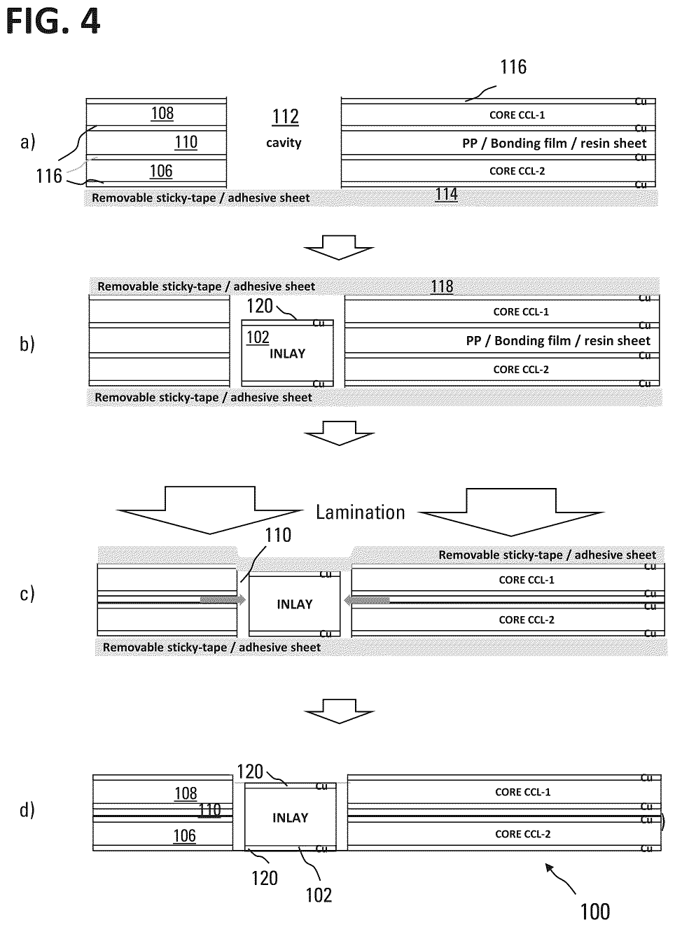

FIG. 4, panels a), b), c) and d) visualize a method of embedding an embeddable object 102 into a stacked substrate 104 in accordance with various embodiments, which is comparable to what is shown in FIG. 2, but without forming the additional metallization layers 122. In this state, the stacked substrate arrangement 100 may be flexibly processed by PCB manufacturers, for example using standard PCB processing.

FIG. 3C leaves open how the embeddable object 102 was arranged in an essentially central vertical position (with respect to the stacked substrate 104), which may for example have been achieved by resting the embeddable object 102 on a suitably sized removable support.

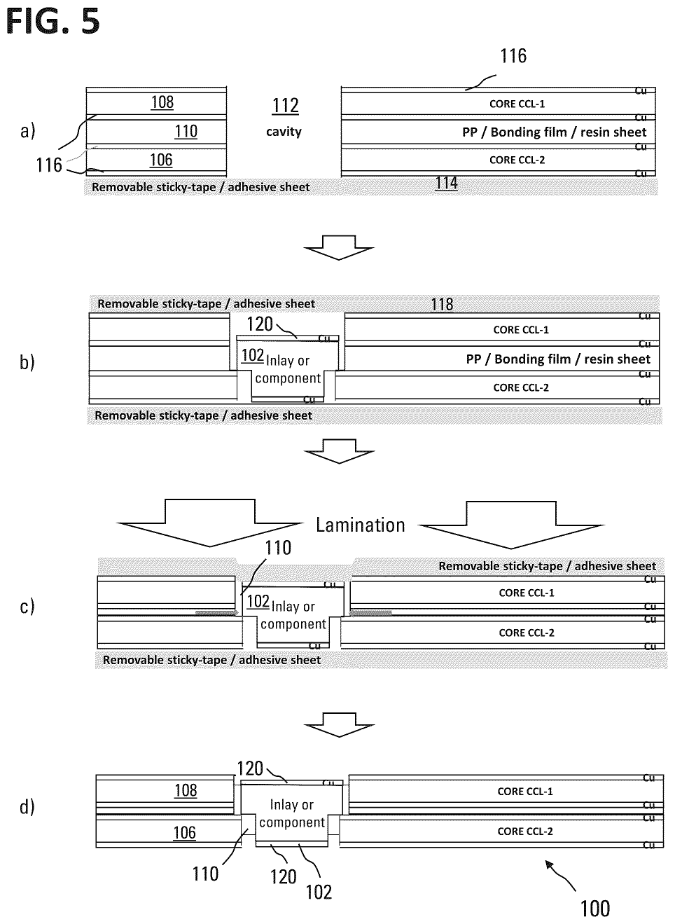

The embodiment shown in FIG. 5, panels a), b), c) and d), visualize a method that allows for an easy positioning of the embeddable object 102 at a defined, but selectable vertical position in the recess 112.

The first layer 106 may be formed with one or more protrusion(s) 550 that protrude into the recess 112. The protrusion(s) 550 may for example form a closed or open ring.

The embeddable object 102 may be rested on the protrusion(s) 550. Depending on the vertical position to be achieved, the embeddable object 102 may have a rectangular cross section, resting on the protrusion(s) 550 with its bottom surface, or may have, as shown in FIG. 5, a T-shaped cross section, and may rest on the first layer 106 with the lower surface of the horizontal T-bar.

The embeddable object 102 with the T-shaped cross section may for example be arranged with its bottom surface flush with a bottom surface of the first layer 106.

The embeddable object 102 with the rectangular cross section may for example be arranged with its upper surface flush with a top surface of the second layer 108.

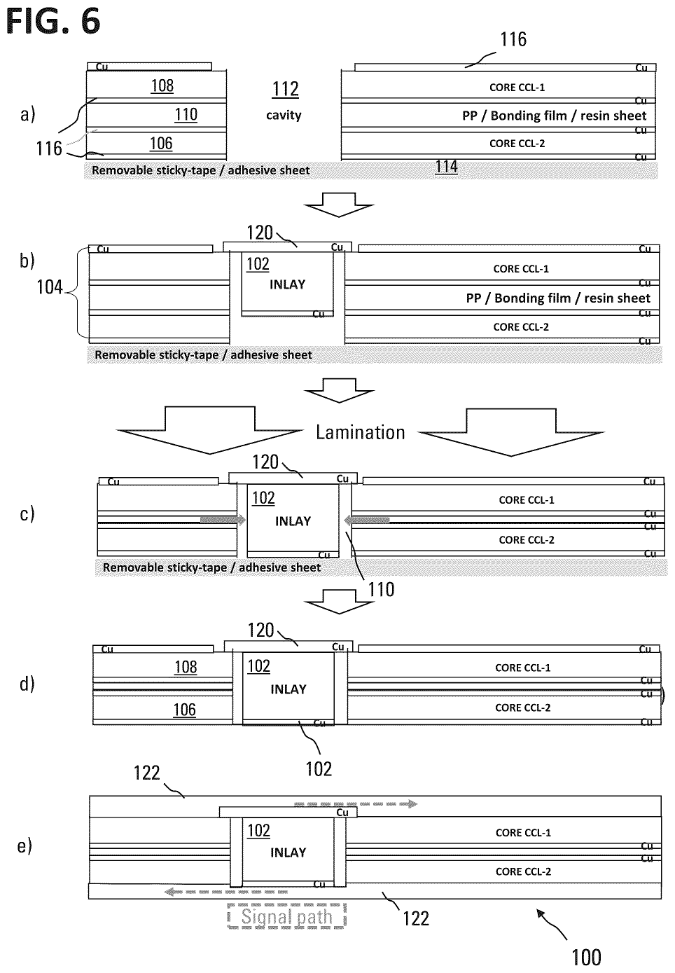

The embodiment shown in FIG. 6, panels a), b), c), d) and e), visualize another method that allows for an easy positioning of the embeddable object 102 at a defined, but selectable vertical position in the recess 112.

The second layer 108 may be formed with a further recess 660 in its top surface, the further recess 660 being connected with the recess 112. The further recess 660 may for example form a ring (or rather, a “negative” ring).

The embeddable object 102 may have a T-shaped cross-section, and may rest on the second layer 108 in the further recess 660 with the lower surface of the horizontal T-bar. Optionally, the horizontal T-bar may be formed by the metallization layer 120 of the embeddable object 102.

The further recess 660, which may for example be obtained by etching, may function as an alignment feature for the embeddable object 102.

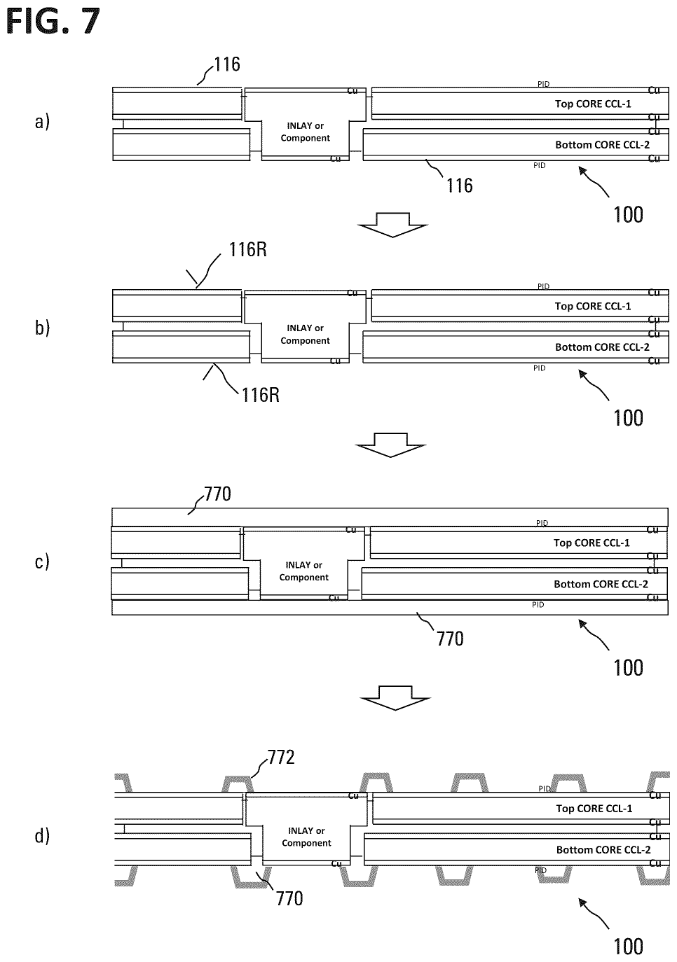

FIG. 7, panels a), b), c) and d), visualize a method of embedding an embeddable object 102 into a stacked substrate 104 in accordance with various embodiments.

The embodiment of FIG. 7 may be similar to FIG. 5 and show further processing of the stacked substrate arrangement 100.

In various embodiments, a surface treatment, e. g., a surface roughening, may be performed on outer (e. g., top and bottom) surfaces of the stacked substrate arrangement 100. For example, the metal layer 116 that may be exposed on the top- and bottom surface, respectively, may be plasma treated to cause plasma induced defects (PID), thereby roughening the surface (indicated in FIG. 7 by reference number 116R) and enhancing an adhesion of the metal layer 116, for example an adhesion to further metal and/or to insulating material to be arranged on the metal layers 116.

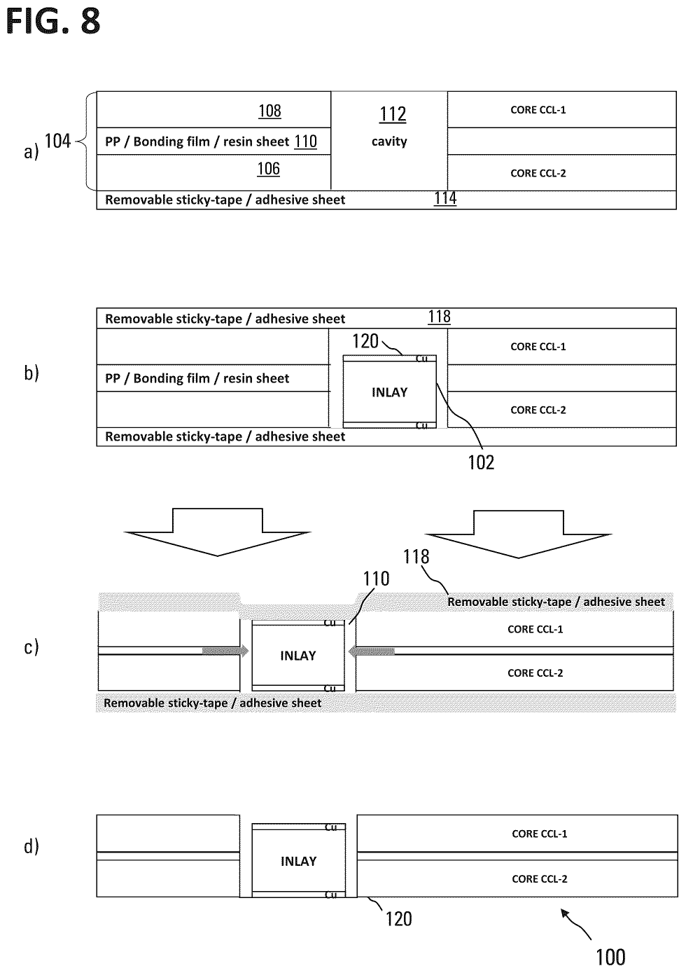

FIG. 8, panels a), b), c) and d), visualize a method of embedding an embeddable object 102 into a stacked substrate 104 in accordance with various embodiments.

The embodiment of FIG. 8 differs from FIG. 2 mainly in that neither the first layer 106 nor the second layer 108 has a metal layer on its surface, which may be suitable if an electrically insulating outer surface of the stacked substrate 104 is required.

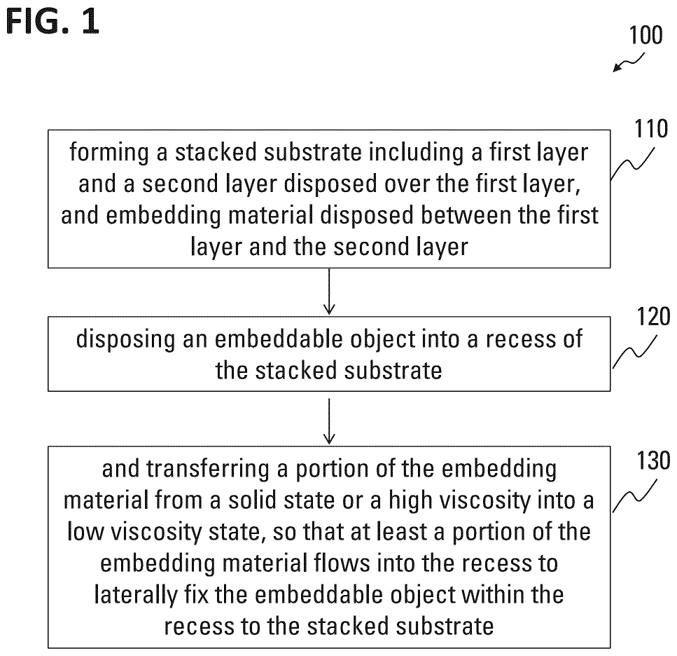

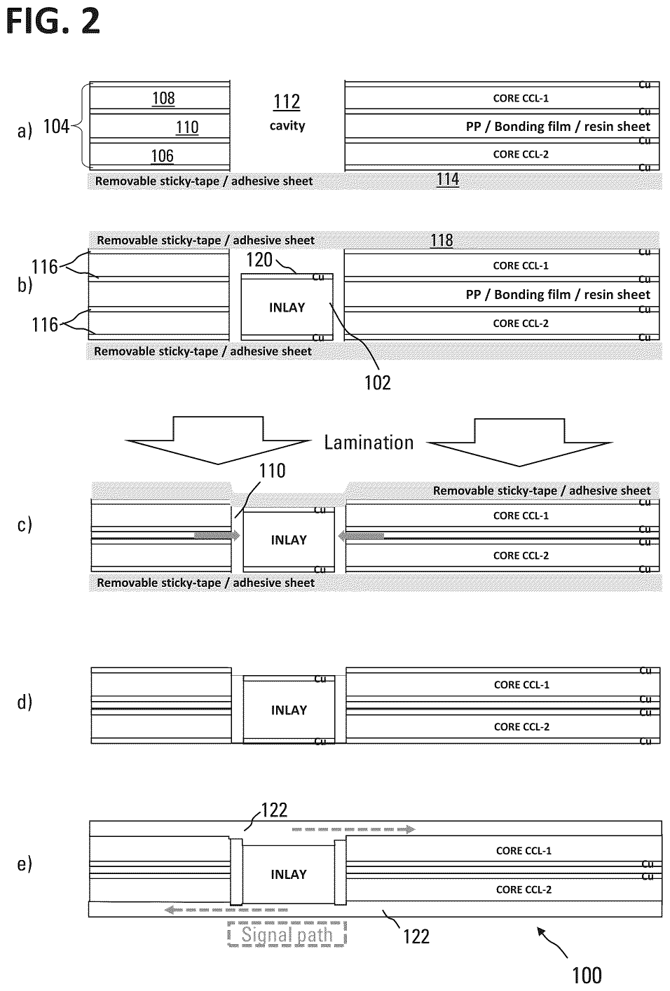

FIG. 1 shows a flow diagram 100 of a method of embedding an embeddable object into a stacked substrate in accordance with various embodiments. The resulting stacked substrate arrangement may correspond to any of the above stacked substrate arrangements 100.

The method includes forming a stacked substrate including a first layer and a second layer disposed over the first layer, and embedding material disposed between the first layer and the second layer (110), disposing the embeddable object into a recess of the stacked substrate (120), and transferring a portion of the embedding material from a solid state or a high viscosity into a low viscosity state, e. g., a flowing state, so that at least a portion of the embedding material flows into the recess to laterally fix the embeddable object within the recess to the stacked substrate (130).

The embeddable object may for example be or include a circuit component like a semiconductor component, a bare die, a magnet, a copper coin or block or any other electrically conductive element.

In the following, various aspects of this disclosure will be illustrated:

Example 1 is a method of embedding an embeddable object into a stacked substrate. The method includes forming a stacked substrate including a first layer and a second layer disposed over the first layer, and embedding material disposed between the first layer and the second layer, disposing the embeddable object into a recess of the stacked substrate, and transferring a portion of the embedding material from a solid state or a high viscosity into a low viscosity state, e. g., a flowing state, so that at least a portion of the embedding material flows into the recess to laterally fix the embeddable object within the recess to the stacked substrate. The embeddable object may for example be or include a circuit component like a semiconductor component, a bare die, a magnet, a copper coin or block or any other electrically conductive element.

In Example 2, the subject matter of Example 1 may optionally further include closing the recess on one side or both sides before the laterally fixing the embeddable object to the stacked substrate.

In Example 3, the subject matter of Example 1 or 2 may optionally further include arranging the stacked substrate on an auxiliary carrier, the first layer facing towards the auxiliary carrier, disposing the embeddable object into the recess of the stacked substrate onto the auxiliary carrier, and, after the laterally fixing the embeddable object to the stacked substrate, removing the auxiliary carrier.

In Example 4, the subject matter of any of Examples 1 to 3 may optionally further include arranging a top layer on the second layer to close the recess.

In Example 5, the subject matter of Example 4 may optionally further include, after the laterally fixing the embeddable object to the stacked substrate, removing the top layer.

In Example 6, the subject matter of Example 5 may optionally include that the arranging the top layer on the second layer further comprises arranging the second layer contacting a top surface of the embeddable object, thereby keeping the top surface of the embeddable object free from the embedding material.

In Example 7, the subject matter of any of Examples 1 to 6 may optionally further include causing the embedding material to flow into the recess using at least one of a group of processes, the group consisting of pressing the first layer against the second layer, heating the embedding material, and/or applying a vacuum in the recess.

In Example 8, the subject matter of any of Examples 1 to 7, may optionally include that the laterally fixing the embeddable object within the recess to the stacked substrate comprises transferring the embedding material from a low viscosity state, e. g., a flowing state, to a solid state or a high viscosity state.

In Example 9, the subject matter of any of Examples 1 to 8, may optionally include that the transferring the embedding material from a low viscosity (e. g., flowing) state to a high viscosity or a solid state comprises at least one of a group of processes, the group consisting of allowing the embedding material to cool down, actively cooling down the embedding material, and curing the embedding material, for example with ultraviolet radiation or by other means known in the art.

In Example 10, the subject matter of any of Examples 1 to 9, further comprising forming the recess in the stacked substrate, thereby exposing at least a portion of the embedding material.

In Example 11, the subject matter of Example 10 may optionally include that the forming the recess in the stacked substrate comprises forming a through-hole in the stacked substrate.

In Example 12, the subject matter of Example 10 may optionally include that the forming the recess in the stacked substrate comprises forming a hole only partway through the stacked substrate.

In Example 13, the subject matter of any of Examples 1 to 12 may optionally include that a total volume of the embedding material disposed between the first layer and the second layer before the laterally fixing the embeddable object to the stacked substrate is larger than a volume of the recess.

In Example 14, the subject matter of any of Examples 1 to 13 may optionally include that the embedding material is disposed, before the transferring a portion of the embedding material from a solid state or a high viscosity into a low viscosity, e. g., a flowing state, as a continuous layer or as a structured layer.

In Example 15, the subject matter of any of Examples 1 to 13 may optionally include that the embedding material is disposed, after the transferring a portion of the embedding material from a solid state or a high viscosity into a low viscosity, e. g., a flowing state, as a continuous layer or as a structured layer.

In Example 16, the subject matter of any of Examples 1 to 15 may optionally include that the embedding material comprises or consists of at least one of a group of materials, the group consisting of a thermoplastic polymer, for example polypropylene, a resin, and a bonding film.

In Example 17, the subject matter of any of Examples 1 to 16 may optionally include that, in the low viscosity, e. g., the flowing state, the embedding material has a viscosity in a range from about 1 mPa·s to about 10⁷ mPa·s.

In Example 18, the subject matter of any of Examples 1 to 17, may optionally include that the first layer and/or the second layer comprises or consists of an insulating material.

In Example 19, the subject matter of Example 18 may optionally include that the insulating material has a melting temperature that is higher than a melting temperature of the embedding material.

In Example 20, the subject matter of Example 19 may optionally include that the insulating material has a viscosity, while the embedding material flows into the recess, that is higher than the viscosity of the embedding material.

In Example 21, the subject matter of any of Examples 18 to 20 may optionally include that the first layer and/or the second layer comprises a metal layer on one or both of their respective main surfaces.

In Example 22, the subject matter of any of Examples 1 to 21 may optionally include that the first layer and the second layer have the same thickness.

In Example 23, the subject matter of any of Examples 1 to 22 may optionally include that a thickness of the embedding material is in a range from about 1 mm to about 10 mm before the at least a portion of the deformable embedding material flowing into the recess.

In Example 24, the subject matter of any of Examples 1 to 23 may optionally include that in a thickness of the embedding material between the first layer and the second layer is in a range from about 1 μm to less than 10 mm after the at least a portion of the deformable embedding material flowing into the recess.

In Example 25, the subject matter of any of Examples 1 to 24 may optionally include that the disposing the embeddable object into the recess comprises resting the embeddable object on a protrusion of the first layer.

In Example 26, the subject matter of any of Examples 1 to 24 may optionally include that the disposing the embeddable object into the recess comprises arranging a portion of the embeddable object on the second layer.

In Example 27, the subject matter of any of Examples 25 or 26 may optionally include that the embeddable object has a T-shaped cross section.

In Example 28, the subject matter of any of Examples 1 to 27 may optionally include that the stacked substrate forms a panel that comprises at least one further recess with at least one further embeddable object.

In Example 29, the subject matter of Example 28 may optionally include that the at least one further embeddable object is embedded into the stacked substrate simultaneously with the embeddable object.

In Example 30, the subject matter of any of Examples 1 to 29 may optionally further include depositing of a metal (e. g., copper) layer over a bottom and/or top of the stacked substrate arrangement.

In Example 31, the subject matter of Example 30 may optionally include that the deposited metal is in contact with a bottom metal layer and/or with a top metal layer.

In Example 32, the subject matter of Example 30 or 31 may optionally include that the deposited metal forms a galvanic connection, e. g., a direct galvanic connection, between the top metal layer of the embeddable object and a metal layer on a top side of the stacked substrate, and/or forms a galvanic connection, e. g., a direct galvanic connection, between the bottom metal layer of the embeddable object and a metal layer on a bottom side of the stacked substrate.

Example 33 is a stacked substrate arrangement. The stacked substrate arrangement includes a stacked substrate including a first layer, a second layer disposed over the first layer, and embedding material, wherein a recess is formed in the first layer and/or the second layer, an embeddable object is arranged in the recess, and the embedding material in the recess laterally fixes the embeddable object within the recess to the stacked substrate, wherein the embedding material in the recess originates from an embedding material reservoir between the first layer and the second layer, such that the embedding material in the recess is homogeneously connected to the embedding material between the first layer and the second layer.

In Example 34, the subject matter of Example 33 may optionally include that a bottom surface of the embeddable object is flush with a surface of the first layer that faces towards a bottom of the stacked substrate, and/or wherein top surface of the embeddable object is flush with a surface of the second layer that faces towards a top of the stacked substrate

In Example 35, the subject matter of Example 33 or 34 may optionally include that the top surface and/or the bottom surface of the embeddable object is free from the embedding material.

In Example 36, the subject matter of any of Examples 33 to 35 may optionally include that the embedding material contacts the embeddable object only laterally.

In Example 37, the subject matter of any of Examples 33 to 35 may optionally include that the embedding material contacts the embeddable object laterally, and additionally on at least one of a top surface and a bottom surface of the embeddable object.

In Example 38, the subject matter of any of Examples 33 to 37 may optionally include that the recess forms a through-hole in the stacked substrate.

In Example 39, the subject matter of any of Examples 33 to 37 may optionally include that the recess forming a hole that extends only partway through the stacked substrate.

In Example 40, the subject matter of any of Examples 33 to 39 may optionally include that the embedding material is disposed as a continuous layer or as a structured layer.

In Example 41, the subject matter of any of Examples 33 to 40 may optionally include that the embedding material comprises or consists of at least one of a group of materials, the group consisting of a thermoplastic polymer, for example polypropylene, a resin, and a bonding film.

In Example 42, the subject matter of any of Examples 33 to 41 may optionally include that the embedding material is in a solid state or a high viscosity state.

In Example 43, the subject matter of any of Examples 33 to 42 may optionally include that, when in a low viscosity, e. g., a flowing state, the embedding material has a viscosity in a range from about 1 mPa·s to about 10⁷ mPa·s.

In Example 44, the subject matter of any of Examples 33 to 43 may optionally include that the first layer and/or the second layer comprises or consists of an insulating material.

In Example 45, the subject matter of Example 44 may optionally include that the insulating material has a melting temperature that is higher than a melting temperature of the embedding material.

In Example 46, the subject matter of Example 44 or 45 may optionally include that the insulating material comprises or consists of glass reinforced epoxy laminate such as FR-4.

In Example 47, the subject matter of any of Examples 33 to 46 may optionally include that the first layer and/or the second layer comprises a metal layer on one or both of their respective main surfaces.

In Example 48, the subject matter of any of Examples 33 to 47 may optionally include that the first layer and/or the second layer are configured as printed circuit boards.

In Example 49, the subject matter of any of Examples 33 to 48 may optionally include that the first layer and the second layer have the same thickness.

In Example 50, the subject matter of any of Examples 33 to 49 may optionally include that a thickness of the embedding material between the first layer and the second layer is in a range from about 1 μm to less than 10 mm after the at least a portion of the deformable embedding material flowing into the recess.

In Example 51, the subject matter of any of Examples 33 to 50 may optionally include that the first layer forms a protrusion into the protruding into the recess, wherein a portion of the embeddable object is arranged on the protrusion.

In Example 52, the subject matter of any of Examples 33 to 51 may optionally include that a portion of the embeddable object is arranged on the second layer.

In Example 53, the subject matter of any of Examples 33 to 52 may optionally include that the embeddable object has a T-shaped cross section.

In Example 54, the subject matter of any of Examples 33 to 53 may optionally include that the stacked substrate arrangement forms a panel that comprises at least one further recess with at least one further embeddable object.

In Example 55, the subject matter of any of Examples 33 to 54 may optionally further include a deposited metal (e. g., copper) layer over a bottom and/or top of the stacked substrate arrangement.

In Example 56, the subject matter of Example 55 may optionally include that the deposited metal is in contact with a bottom metal layer and/or with a top metal layer.

In Example 57, the subject matter of Example 55 or 56 may optionally include that the deposited metal forms a galvanic connection, e. g., a direct galvanic connection, between the top metal layer of the embeddable object and a metal layer on a top side of the stacked substrate, and/or forms a galvanic connection, e. g., a direct galvanic connection, between the bottom metal layer of the embeddable object and a metal layer on a bottom side of the stacked substrate.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of embedding an embeddable object into a stacked substrate, the method comprising:
forming a stacked substrate comprising a first layer and a second layer disposed over the first layer, and embedding material disposed between the first layer and the second layer;
disposing the embeddable object into a recess of the stacked substrate; and
transferring a portion of the embedding material from a solid state or a high viscosity into a low viscosity state, so that at least a portion of the embedding material flows into the recess to laterally fix the embeddable object within the recess to the stacked substrate.

2. The method of claim 1, further comprising:
closing the recess on one side or both sides before the laterally fixing the embeddable object to the stacked substrate.

3. The method of claim 1, further comprising:
arranging the stacked substrate on an auxiliary carrier, the first layer facing towards the auxiliary carrier;
disposing the embeddable object into the recess of the stacked substrate onto the auxiliary carrier; and
after the laterally fixing the embeddable object to the stacked substrate, removing the auxiliary carrier.

4. The method of claim 1, further comprising:
arranging a top layer on the second layer to close the recess.

5. The method of claim 1, further comprising:
causing the embedding material to flow into the recess using at least one of a group of processes, the group consisting of:
pressing the first layer against the second layer;
heating the embedding material; and/or
applying a vacuum in the recess.

6. The method of claim 1,
wherein the transferring the embedding material from a low viscosity state to a solid state or a high viscosity state comprises at least one of a group of processes, the group consisting of:
allowing the embedding material to cool down;
actively cooling down the embedding material; and
curing the embedding material with ultraviolet radiation.

7. The method of claim 1, further comprising:
forming the recess in the stacked substrate, thereby exposing at least a portion of the embedding material.

8. The method of claim 7:
wherein the forming the recess in the stacked substrate comprises forming a through-hole in the stacked substrate.

9. The method of claim 1,
wherein a total volume of the embedding material disposed between the first layer and the second layer before the laterally fixing the embeddable object to the stacked substrate is larger than a volume of the recess.

10. The method of claim 1,
wherein the embedding material is disposed, before the transferring a portion of the embedding material from a solid state or a high viscosity into a low viscosity state, as a continuous layer or as a structured layer.

11. The method of claim 1,
wherein the embedding material is disposed, after the transferring a portion of the embedding material from a solid state or a high viscosity state into a low viscosity state, as a continuous layer or as a structured layer.

12. The method of claim 1,
wherein the embedding material comprises or consists of at least one of a group of materials, the group consisting of:
a thermoplastic polymer, for example polypropylene;
a premixed or one-part adhesive; and
a bonding film.

13. The method of claim 1,
wherein, in the low viscosity state, the embedding material has a viscosity in a range from about 1 mPa·s to about 10⁷ mPa·s.

14. The method of claim 1,
wherein the first layer and/or the second layer comprises or consists of an insulating material.

15. The method of claim 14,
wherein the insulating material has a melting temperature that is higher than a melting temperature of the embedding material.

16. The method of claim 14,
wherein the first layer and/or the second layer comprises a metal layer on one or both of their respective main surfaces.

17. The method of claim 1, further comprising:
depositing of a metal layer over a bottom and/or top of the stacked substrate arrangement.

18. A stacked substrate arrangement, comprising:
a stacked substrate comprising a first layer, a second layer disposed over the first layer, and embedding material disposed between the first layer and the second layer;
a recess formed in the first layer and/or the second layer; and
an embeddable object arranged in the recess;
wherein the embedding material in the recess laterally fixes the embeddable object within the recess to the stacked substrate; and
wherein the embedding material in the recess originates from an embedding material reservoir between the first layer and the second layer, such that the embedding material in the recess is homogeneously connected to the embedding material between the first layer and the second layer.

19. The stacked substrate arrangement of claim 18,
wherein bottom surface of the embeddable object is flush with a surface of the first layer that faces towards a bottom of the stacked substrate; and/or
wherein top surface of the embeddable object is flush with a surface of the second layer that faces towards a top of the stacked substrate.

20. The stacked substrate arrangement of claim 18:
wherein the recess forms a through-hole in the stacked substrate.

21. The stacked substrate arrangement of claim 18,
wherein the embedding material comprises or consists of at least one of a group of materials, the group consisting of:
a thermoplastic polymer, for example polypropylene;
a resin; and
a bonding film.

22. The stacked substrate arrangement of claim 18,
wherein the embedding material is in a solid state or a high viscosity state.

23. The stacked substrate arrangement of claim 18,
wherein, when in a low viscosity state, the embedding material has a viscosity in a range from about 1 mPa·s to about 10⁷ mPa·s.

24. The stacked substrate arrangement of claim 18,
wherein the first layer and/or the second layer comprises or consists of an insulating material that has a melting temperature that is higher than a melting temperature of the embedding material.

25. The stacked substrate arrangement of claim 24,
wherein the insulating material comprises or consists of glass reinforced epoxy laminate such as FR-4.

26. The stacked substrate arrangement of claim 18,
wherein the first layer and/or the second layer comprises a metal layer on one or both of their respective main surfaces.

27. The stacked substrate arrangement of claim 18,
wherein the first layer and/or the second layer are configured as printed circuit boards.

28. The stacked substrate arrangement of claim 18,
wherein the first layer and the second layer have the same thickness.

29. The stacked substrate arrangement of claim 18,
wherein a thickness of the embedding material between the first layer and the second layer is in a range from about 1 μm to less than 10 mm after the at least a portion of the deformable embedding material flowing into the recess.

30. The stacked substrate arrangement of claim 18,
wherein the embeddable object has a T-shaped cross section.

31. The stacked substrate arrangement of claim 18, further comprising:
a deposited metal layer over a bottom and/or top of the stacked substrate arrangement.
